(19) United States
(12) Patent Application Publication
(10) Pub. No.: US 2011/0254077 A1
(43) Pub. Date: Oct. 20, 2011

(54) SEMICONDUCTOR DEVICE AND METHOD OF FABRICATING THE SAME

(76) Inventors: Chang-Sup Lee, Yongin-si (KR); Jongho Park, Seoul (KR); Sung-Hun Lee, Yongin-si (KR); Ki-Yong Kim, Suwon-si (KR)

(21) Appl. No.: 13/079,382

(22) Filed: Apr. 4, 2011

(30) Foreign Application Priority Data
Apr. 16, 2010 (KR) 10-2010-0035424

(51) Int. Cl. H01L 29/78

(52) U.S. Cl. 257/324; 257/E29.255

(57) ABSTRACT

A semiconductor device includes a plurality of gate structures disposed on a substrate. Respective gate structures may include a lower control gate layer and an upper control gate layer. The upper control gate layer may be disposed on the lower control gate layer and may include a different material from the lower control gate layer. The semiconductor device may further include insulation patterned layers disposed in gap regions defined between the gate structures adjacent to each other. Upper surfaces of the insulation patterned layers may be lower than an upper surface of the lower control gate layer.

### CROSS-REFERENCE TO RELATED APPLICATIONS

This U.S. non-provisional patent application claims priority under 35 U.S.C. §119 of Korean Patent Application No. 10-2010-0035424, filed on Apr. 16, 2010, the entire contents of which are hereby incorporated by reference.

### BACKGROUND

The present disclosure herein relates to a semiconductor device and method of fabricating the same.

As semiconductor devices has been used in almost every field of industry such as automobile and ship building as well as various electronic devices, the position of a semiconductor industry in a modern industrial structure is becoming higher day by day. As semiconductor devices are used in various industrial fields as in the foregoing and has become an important element to decide qualities of the electronic devices, automobiles and/or ships, needs for semiconductor devices having superior characteristics are also increasing. Such needs require semiconductor technologies to implement high-density, low power consumption and/or high-speed semiconductor devices.

### SUMMARY

An embodiment of the inventive concept may include a semiconductor device comprising a plurality of gate structures disposed on a substrate. Respective gate structures may include a lower control gate layer and an upper control gate layer. The upper control gate layer may be disposed on the lower control gate layer and may include a different material from the lower control gate layer. The embodiment of the inventive concept may further include insulation patterned layers disposed in gap regions defined between the gate structures adjacent to each other. Upper surfaces of the insulation patterned layers may be lower than an upper surface of the lower control gate layer.

At least one of the plurality of gate structures includes a tunnel dielectric layer, a charge storage layer, and a blocking layer sequentially stacked between the substrate and the lower control gate. The upper surfaces of the insulation patterned layers are higher than an upper surface of the blocking layer. The upper surfaces of the insulation patterned layers are substantially even.

At least one of the plurality of gate structures comprises an underlying gate layer disposed between the substrate and the lower control gate, a gate dielectric layer disposed between the underlying gate layer and the substrate, and an inter-gate dielectric layer disposed between the underlying gate layer and the lower control gate layer. The lower control gate layer may be in contact with the underlying gate layer penetrating through the inter-gate dielectric layer. The lower control gate layer includes a first upper surface and second upper surfaces disposed on both sides of the first upper surface. The second upper surfaces may be lower than the first upper surface. The upper surfaces of the insulation patterned layers are lower than the second upper surface.

An interlayer dielectric layer may be disposed on the insulation patterned layers and the plurality of gate structures. The insulation patterned layers may have protruded portions at both sides of the upper surfaces of the insulation patterned layers. Spacers are disposed on the protruded portions and sidewalls of the upper control gate layer. The protruded portions have sidewalls self-aligned to the sidewalls of the spacers. A resistivity of the upper control gate layer is lower than a resistivity of the lower control gate layer. The different material comprises a metal.

Another embodiment of the inventive concept may include a method of manufacturing a semiconductor device. The method may include the step of forming a plurality of gate structures including a control gate layer on a substrate, the step of forming insulation patterned layers disposed between the adjoining gate structures, the step of performing a metal-semiconductor compounding process to change a portion of the control gate layer into a metal semiconductor compound, and the step of recessing the insulation patterned layer after performing the metal-semiconductor compounding process. Upper surfaces of the insulation patterned layers may be lower than an upper surface of the control gate layer.

In accordance with the metal-semiconductor compounding process, the control gate layer comprises an upper control gate layer formed of a metal-semiconductor compound and a lower control gate layer made of an unreacted portion of the control gate layer. Upper surfaces of the recessed insulation patterned layers are lower than an upper surface of the lower control gate layer.

The step of performing a metal-semiconductor compounding process comprises the step of forming a metal layer on the plurality of gate structures and the insulation patterned layers, the step of reacting the metal layer with the upper portion of the control gate layer to form the metal semiconductor compound, and the step of removing an unreacted portion of the metal layer. The step of forming a metal layer is performed in-situ with the step of reacting the metal layer.

The step of performing a metal-semiconductor compounding process includes the step of conformally forming a spacer layer having a thickness less than half width of a space between the adjoining gate structures before the step of recessing the insulation pattern. The step of performing a metal-semiconductor compounding process further include the step of anisotropically etching the spacer layer to form spacers on sidewalls of the upper control gate layer before the step of recessing the insulation patterned layer.

The method further includes the step of forming an interlayer dielectric layer on the recessed upper surface and the gate structures.

Another embodiment may include a semiconductor device comprising a first gate structure including a lower control gate layer and an upper control gate layer that include a metal silicide, a second gate structure including a lower control gate and an upper control gate layer and being distant from the first gate structure at a first space width, and a first isolation patterned layer filling a gap between the first and the second gate structure. An upper surface of the first isolation patterned layer is lower than an upper surface of the lower control gate layer of the first gate structure.

The semiconductor device further comprises a third gate structure including a lower control gate layer and an upper control gate layer that a metal silicide and a fourth gate structure including a lower control gate and an upper control gate layer. The fourth gate structure is distant from the third gate structure at a second space width. The second space width is larger than the first space width. The semiconductor device further comprises a second isolation patterned layer filling a gap between the third and the fourth gate structure. An upper surface of the second isolation patterned layer is lower than an upper surface of the lower control gate layer of the third gate structure. The upper surface of the upper surface of the second isolation patterned layer is lower than the upper surface of the first isolation patterned layer.

### BRIEF DESCRIPTION OF THE DRAWINGS

FIG. 1 is a cross sectional view illustrating a semiconductor device according to one exemplary embodiment of the present inventive concept.

FIGS. 2 through 5 are cross sectional views illustrating a method of manufacturing the semiconductor device as shown in FIG. 1.

FIG. 6 is a cross sectional view illustrating a semiconductor device according to another exemplary embodiment of the present inventive concept.

FIGS. 7 through 8 are cross sectional views illustrating a method of manufacturing the semiconductor device as shown in FIG. 6.

FIG. 9 is a block diagram illustrating an electronic system including the semiconductor device according to exemplary embodiments of the present inventive concept.

FIG. 10 is a block diagram illustrating a memory card including the semiconductor device according to exemplary embodiments of the present inventive concept.

### DETAILED DESCRIPTION OF THE EMBODIMENTS

Hereinafter, exemplary embodiments of the present inventive concept will be explained in detail with reference to the accompanying drawings. The embodiments of the present inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

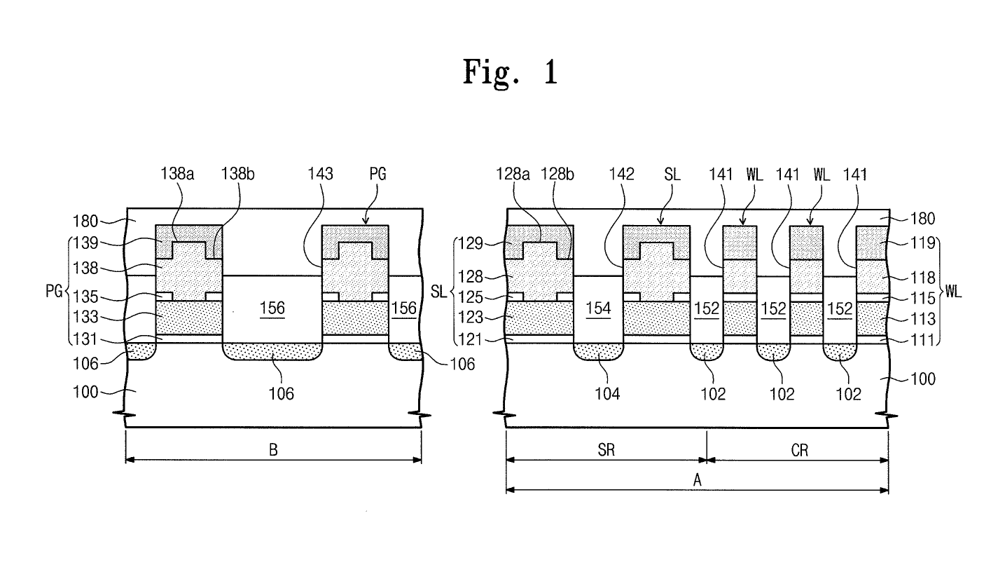

It will be understood that when a film (or a layer) is referred to as being “on” another film (or a layer), it can be directly on the other film or intervening elements may also be present. In the drawings, the sizes and thicknesses of films (or layers) and regions are exaggerated for clarity. It will be understood that, although the terms first, second, third etc. may be used herein to describe various regions and films (or layers), these regions and films should not be limited by these terms. These terms are only used to distinguish one region or one film (or a layer) from another region or another film (or another layer). Thus, a first film in some embodiments could be termed a second film in other embodiments. Exemplary embodiments of the present inventive concept explained and illustrated herein include their complementary counterparts. The term “and/or” in this specification is used to mean to include at least one of the associated listed items. Like numerals in this specification refer to like elements throughout. Hereinafter, a semiconductor device according to an exemplary embodiment of the present inventive concept will be explained. FIG. 1 is a cross sectional view illustrating the semiconductor device according to the exemplary embodiment of the present inventive concept.

Referring to FIG. 1, a semiconductor device according to an embodiment of the present inventive concept may include a substrate 100 having a string region A and a peripheral region B separated from each other. The substrate 100 may be a semiconductor substrate. For example, the substrate 100 may be a silicon substrate, a germanium substrate, a silicon-germanium substrate, or a compound semiconductor substrate. The substrate 100 may be doped with a first type dopant.

The string region A may include a select region SR and a memory cell region CR. Select transistors are formed in the select region SR, and cell transistors are formed in the memory cell region CR. Peripheral transistors are formed in the peripheral region B. Device isolation patterns (not shown here) are formed in the substrate 100 to define peripheral active regions within the peripheral region B and to define string active regions within the string region A. The string active region may extend from the memory cell region CR into the select region SR. In other words, the string active regions may be defined within the memory cell region CR and the select region SR. The respective peripheral and string active regions may be a portion of the substrate 100 surrounded by the device isolation patterns (not shown here). The respective peripheral and string active regions may include channel regions. When the semiconductor device operates, a channel may be formed in the channel regions.

Peripheral gate structures PG of the peripheral transistors are disposed on the peripheral active region and select lines SL and word lines WL of the cell transistors are disposed on the string active region. The select lines SL may be disposed on the string active region within the select region SR and the word lines WL may be disposed on the string active region within the memory cell region CR.

The word lines WL may be gate structures of the cell transistors and may be separately disposed from each other with a first space on the memory cell region CR. Source/drain regions 102 of the cell transistors may be provided in the substrate 100 between adjoining word lines WL. The source/drain regions 102 may be regions doped by a second type dopant, and may include an inversion layer generated by an operation voltage applied to control gate layers 118,119. Specifically, the inversion layer may be generated by a fringe field generated at the control gate layers 118, 119 due to the operation voltage.

The respective word lines WL may include a tunnel dielectric layer 111, a charge storage layer 113 on the tunnel dielectric layer 111, a blocking layer 115 on the charge storage layer 113, and the control gate layer 118, 119 on the blocking layer 115, which are disposed on the string active region. The tunnel dielectric layer 111, the charge storage layer 113, the blocking layer 115, the control gate layer 118, 119 may be sequentially stacked on the substrate 100. The control gate layers 118, 119 are disposed on the blocking layer 115 in such a manner as to traverse the active region.

The tunnel dielectric layer 111 may include a single layer or multiple layers. For example, the tunnel dielectric layer 111 may include at least one selected from the group consisting of a silicon oxynitride, a silicon nitride, a silicon oxide, and a metal oxide layer.

The charge storage layer 113 may include a doped polysilicon or undoped polysilicon. The charge storage layer 113 may include charge trap sites to store charges. For example, the charge storage layer 113 may include at least one selected from the group consisting of a silicon nitride, a metal nitride, a metal oxynitride, a metal silicon oxide, a metal silicon oxynitride, and nano-dots.

The blocking layer 115 may include a material having a higher dielectric constant than the tunnel dielectric layer 111. The blocking layer 115 may include at least one selected from the group consisting of a silicon oxide, a silicon nitride, a silicon oxynitride, and a high dielectric layer. The high dielectric layer may include at least one selected from the group consisting of a metal oxide, a metal nitride, and a metal oxynitride layer. The high dielectric layer may include Hafnium (Hf), Zirconium (Zr), Aluminum (Al), Tantalum (Ta), Lanthanum (La), Cerium (Ce), or Praseodymium (Pr).

The control gate layers 118, 119 may include a lower control gate layer 118 on the blocking layer 115 and an upper control gate layer 119 on the lower control gate layer 118. The upper control gate layer 119 may include a different material from the lower control gate layer 118. The different material may be metal. For example, the lower control gate layer 118 may include a doped and/or undoped polysilicon, and the upper control gate layer 119 may include a metal silicide. For example, the metal silicide may be a tungsten silicide, titanium silicide, a cobalt silicide or a tantalum silicide. The resistivity of the upper control gate layer 119 may be lower than a resistivity of the lower control gate layer 118.

The select lines SL may be gate structures of the cell transistors and may be separately disposed on the select region SR from each other with a second space wider than the first space on the cell region CR. The adjoining select lines SL and the word lines WL may be separated from each other by the first space. An impurity region 104 may be provided between the adjoining select lines SL. In the case that the select lines SL are ground select lines, the impurity region 104 may be a common source region. In the case that the select lines SL are string select lines, the impurity region 104 may be a common drain region. The impurity region 104 may be a region doped with the second type dopant.

The select lines SL may include a select gate dielectric layer 121 disposed on the select region SR, a select underlying gate layer 123 on the select gate dielectric layer 121, an inter-select gate dielectric layer 125 on the select underlying gate layer 123, a select lower control gate layer 128 on the inter-select gate dielectric layer 125 and the select upper control gate layer 129 on the select lower control gate layer 128. The select lower control gate layer 128 may contact the select underlying gate layer 123 penetrating through the inter-select gate dielectric layer 125.

The select lower control gate layer 128 may include a first upper surface 128a and a second upper surface 128b disposed on both sides of the first upper surface 128a. The second upper surface 128b of the select lower control gate layer 128 may be lower than the first upper surface 128a of the select lower control gate layer 128. The first and second upper surfaces 128a, 128b of the select lower control gate layer 128 may contact the bottom surface of the select upper control gate layer 129.

The select gate dielectric layer 121, the select underlying gate layer 123, the inter-select gate dielectric layer 125, the select lower control gate layer 128 and the select upper control gate layer 129 may be formed of the same material as the tunnel dielectric layer 111, the charge storage layer 113, the blocking layer 115, the lower control gate layer 118 and the upper control gate layer 119, respectively.

Peripheral gate structures PG may be gate structures of the peripheral transistors and may be separately disposed on the peripheral region B from each other with a third space wider than the first space on the cell region CR. Peripheral source/drain region 106 may be provided in the substrate 100 between the adjoining peripheral gate structures PG. The peripheral source/drain region 106 may be a region doped with the second type dopant.

The peripheral gate structures PG may include a peripheral gate dielectric layer 131 on the substrate 100, a peripheral underlying gate layer 133 on the peripheral gate dielectric layer 131, a inter-peripheral gate dielectric layer 135 on the peripheral underlying gate layer 133, a peripheral lower control gate layer 138 on the inter-peripheral gate dielectric layer 135, and a peripheral upper control gate layer 139 on the peripheral lower control gate layer 138. The peripheral lower control gate layer 138 may contact the peripheral underlying gate layer 133 penetrating through the inter-peripheral gate dielectric layer 135.

The peripheral lower control gate layer 138 may include a first upper surface 138a and a second upper surface 138b disposed on both sides of the first upper surface 138a. The second upper surface 138b of the peripheral lower control gate layer 138 may be lower than the first upper surface 138a of the peripheral lower control gate layer 138. The first and second upper surfaces 138a, 138b of the peripheral lower control gate layer 138 may contact the bottom surface of the peripheral upper control gate layer 139.

The peripheral gate dielectric layer 131, the peripheral underlying gate layer 133, the inter-peripheral gate dielectric layer 135, the peripheral lower control gate layer 138 and the peripheral upper control gate layer 139 may be formed of the same material as the tunnel dielectric layer 111, the charge storage layer 113, the blocking layer 115, the lower control gate layer 118 and the upper control gate layer 119, respectively.

Gap regions 141, 142, 143 may be defined between the adjoining gate structures WL, SL, PG. First gap regions 141 may be defined between the adjoining word lines WL and may also be defined between the adjoining word lines WL and select line SL. A second gap region 142 may be defined between the adjoining select lines SL. A third gap region 143 may be defined between the adjoining peripheral gate structures PG. The lower surfaces of the respective gap regions 141, 142, 143 may correspond to an upper surface of the source/drain regions 102, 104, 106 in the substrate 100, and the sidewalls of the respective gap regions 141, 142, 143 may correspond to the sidewalls of the gate structures WL, SL, PG. The first gap regions 141 may be narrower than the second and third gap regions 142, 143.

Insulation patterned layers 152, 154, 156 may be provided to fill the lower regions of the respective gap regions 141, 142, 143. For example, the lower portion of the first gap regions 141 may be filled with a first insulation patterned layer 152, the lower region of the second gap region 142 may be filled with a second insulation patterned layer 154, and the lower region of the third gap region 143 may be filled with a third insulation patterned layer 156. The insulation patterned layers 152, 154, 156 may completely fill the lower regions of the respective gap regions 141, 142, 143. The insulation patterned layers 152, 154, 156 may include a silicon oxide.

The respective insulation patterned layers 152, 154, 156 may include upper surfaces. The upper surfaces of the respective insulation patterned layers 152, 154, 156 may be substantially even. The upper surfaces of the respective insulation patterned layers 152, 154, 156 may be parallel to the upper surface of the substrate. The upper surfaces of the respective insulation patterned layers 152, 154, 156 may have a substantially same height. Alternatively, the upper surfaces of the second and third insulation patterned layers 154, 156 may be lower than the upper surface of the first insulation patterned layers 152.

The upper surfaces of the first insulation patterned layers 152 may be lower than the upper surface of the lower control gate layer 118 and may be higher than the upper surface of the blocking layer 115. The upper surface of the second insulation patterned layer 154 may be lower than the second upper surface 128b of the select lower control gate layer 128 and may be higher than the upper surface of the inter-select gate dielectric layer 125. The upper surface of the third insulation patterned layer 156 may be lower than the second upper surface 138b of the peripheral lower control gate layer 138 and may be higher than the upper surface of the inter-peripheral gate dielectric layer 135.

An interlayer dielectric layer 180 may be disposed on the insulation patterned layers 152, 154, 156 and the gate structures WL, SL, PG. The interlayer dielectric layer 180 may fill the upper portion of the gap regions 141, 142, 143. The interlayer dielectric layer 180 may include a silicon oxide.

According to the present inventive concept, the upper surfaces of the insulation patterned layers 152, 154, 156 disposed between the adjoining gate structures WL, SL, PG may be lower than the upper surface of the lower control gate layer 118 and may also be lower than the second upper surfaces of the lower control gate layers 128, 138. As a result, the upper control gate layers of the adjoining gate structures WL, SL, PG may avoid short circuit failures due to the diffusion of the metal material in the upper control gate layers 119, 129, 139.

If the upper surfaces of the insulation patterned layers 152, 154, 156 filling the gap regions 141, 142, 143 have such heights as to contact the upper control gate layers 119, 129, 139, the metal materials contained in the upper control gate layers 119, 129, 139 may diffuse along the boundaries between insulation patterned layers 119, 129, 139 and the interlayer dielectric layer 180. As a result, the upper control gate layers 119, 129, 139 can be electrically short-circuited with their adjoining the upper control gate layers 119, 129, 139.

According to the present inventive concept, however, the upper surfaces of the insulation patterned layers 152, 154, 156 are lower than the upper surface and the second upper surface of the lower control gate layers 118, 128, 138, thereby preventing short circuit failures between the control gate layers of the adjoining gate structures WL, SL, PG. Therefore, a highly reliable semiconductor device can be provided.

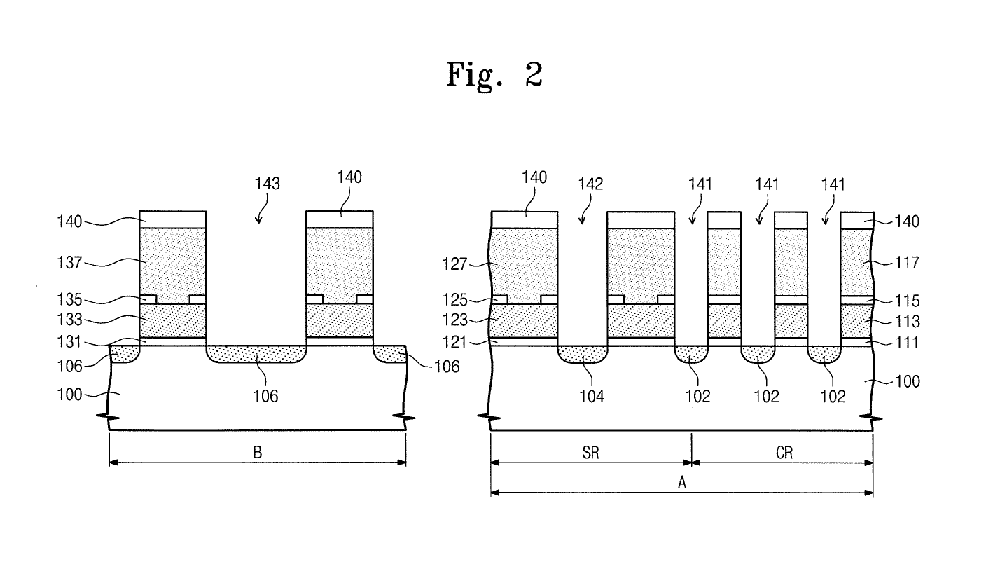

Hereinafter, a semiconductor device manufacturing method according to an exemplary embodiment of the present inventive concept will be explained. FIGS. 2 through 5 are cross sectional views illustrating a method of manufacturing the semiconductor device as shown in FIG. 1.

Referring to FIG. 2, a substrate 100 includes a string region A and a peripheral region B. The string region A may include a memory cell region CR and a select region SR. Cell gate patterned layers 111, 113, 115, 117 and select gate patterned layers 121, 123, 125, 127 may be disposed on the substrate 100 within the memory cell region CR and within the select region SR of the string region A, respectively. Peripheral gate patterned layers 131, 133, 135, 137 may be disposed on the substrate 100 within the peripheral region B.

The cell gate patterned layers 111, 113, 115, 117 may be separately disposed from each other with a first space on the memory cell region CR. The cell gate patterned layers 111, 113, 115, 117 may include the tunnel dielectric layer 111, the charge storage patter 113, and the blocking layer 115, as explained referring to FIG. 1. The cell gate patterned layers 111, 113, 115, 117 may include a control gate layer 117 on the blocking layer 115. The control gate layer 117 may include a doped or undoped polysilicon.

The select gate patterned layers 121, 123, 125, 127 may be separately disposed from each other with a second space on the select region SR. The second space is wider that the first space. The select gate patterned layers 121, 123, 125, 127 may include a select gate dielectric layer 121, a select underlying gate 123, an inter-select gate dielectric layer 125. The select gate patterned layers 121, 123, 125, 127, as explained referring to FIG. 1, may include a select control gate layer 127 on the inter-select gate dielectric layer 125. The select control gate layer 127 may contact the select underlying gate 123 penetrating through the inter-select gate dielectric layer 125. The select control gate layer 127 may include the same material as the control gate layer 117.

Peripheral gate patterned layers 131, 133, 135, 137 may be seperately disposed from each other with a third space on the peripheral region B. The third space is wider than the first space. The peripheral gate patterned layers 131, 133, 135, 137, as explained referring to FIG. 1, may include a peripheral gate dielectric layer 131, a peripheral underlying gate 133, and an inter-peripheral gate dielectric layer 135. The peripheral gate patterned layers 131, 133, 135, 137 may include a peripheral control gate layer 137 on the inter-peripheral gate dielectric layer 135. The peripheral control gate layer 137 may contact the peripheral underlying gate 133 penetrating through the inter-peripheral gate dielectric layer 135. The peripheral control gate layer 137 may include the same material as the control gate layer 117.

Capping patterned layers 140 may be provided on the cell gate patterned layers 111, 113, 115, 117, the select gate patterned layers 121, 123, 125, 127, and the peripheral gate patterned layers 131, 133, 135, 137. The capping patterned layers 140 may include an oxide, a nitride, and/or an oxynitride material.

First gap regions 141 may be defined between the adjoining cell gate patterned layers 111, 113, 115, 117 and between the adjoining cell gate patterned layers 111, 113, 115, 117 and the select gate patterned layers 121, 123, 125, 127. A second gap region 142 may be defined between the adjoining select gate patterned layers 121, 123, 125, 127. A third gap region 143 may be defined between the adjoining peripheral gate patterned layers 131, 133, 135, 137. The lower surfaces of the respective gap regions 141, 142, 143 may correspond to an upper surface of the substrate 100 and the sidewalls of the respective gap regions 141, 142, 143 may correspond to the sidewalls of the gate patterned layers. The first gap regions 141 may be narrower than the second and the third gap regions 142, 143.

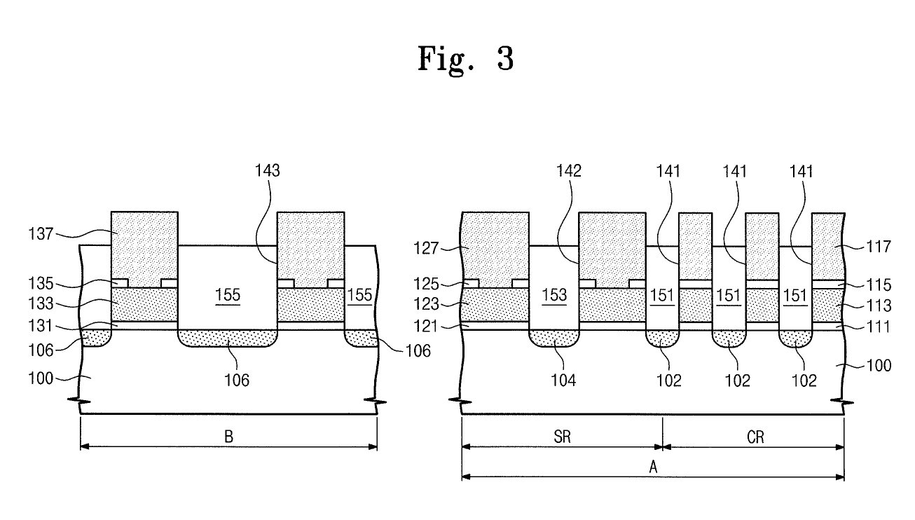

Referring to FIG. 3, insulation patterned layers 151, 153, 155 may be formed to fill the lower region of the respective gap regions 141, 142, 143. The insulation patterned layers 151, 153, 155 may be formed by providing an insulation layer deposited on the gate patterned layers and partially etching the insulation layer. As a result, the insulation patterned layers 151, 153, 155 may entirely fill the lower portion of the gap regions 141, 142, 143. The insulation patterned layers 151, 153, 155 are the portions of the insulation layer remaining in the gap regions 141, 142, 143 after partially etching the insulation layer. The capping patterned layers 140 may be removed while the insulation layer is etched. The insulation layer may include a silicon oxide material.

The upper surfaces of the first insulation patterned layers 151 may be lower than the upper surface of the control gate layer 117 and may also be higher than the upper surface of the blocking layer 115. The upper portion of the control gate layer 117 may be exposed from the first insulation patterned layers 151. The upper surface of the second insulation patterned layers 153 filling the lower region of the second gap region 142 may be lower than the upper surface of the select control gate layer 127 and may also be higher than the upper surface of the inter-select gate dielectric layer 125. The upper portion of the select control gate layer 127 may be exposed from the second insulation patterned layer 153. The upper surface of the third insulation patterned layers 155 may be lower than the upper surface of the peripheral control gate layer 137 and may also be higher than the upper surface of the inter-peripheral gate dielectric layer 135. The upper portion of the peripheral control gate layer 137 may be exposed from the third insulation patterned layers 155.

A metal-semiconductor compounding process may be performed to the upper portion of the control gate layers 117, 127, 137 exposed above the upper surface of the insulation patterned layers 151, 153, 155. The metal-semiconductor compounding process is a process of forming a metal-semiconductor compound by reacting metal with semiconductor. For example, in the case that the control gate layer 117, 127, 137 are formed of silicon, the metal-semiconductor compounding process may be a metal silicidation process. The metal silicidation process may be a tungsten silicidation process, a titanium silicidation process, a cobalt silicidation process or tantalum silicidation process.

The metal-semiconductor compounding process will be explained in detail. A metal layer can be deposited on the exposed upper portions of the control gate layers 117, 127, 137. The deposited metal layer can contact the exposed upper portions of the control gate layers 117, 127, 137. The deposited metal layer and the exposed upper portions of the control gate layers 117, 127, 137 may react with each other to form a metal-semiconductor compound.

The deposition of the metal layer may be performed in-situ with the reaction of the deposited metal layer with the exposed portions of the control gate layers 117, 127, 137. For example, in the chamber performing the metal layer deposition process, the deposited metal layer may react with the exposed portions of the control gate layers 117, 127, 137. After forming a metal-semiconductor compound by a metal-semiconductor compounding process, the remaining metal layer that does not react with the portions of the exposed control gate layers 117, 127, 137 is removed. The removal of the unreacted remaining metal layer may expose the upper surfaces of the insulation patterned layers 151, 153, 155.

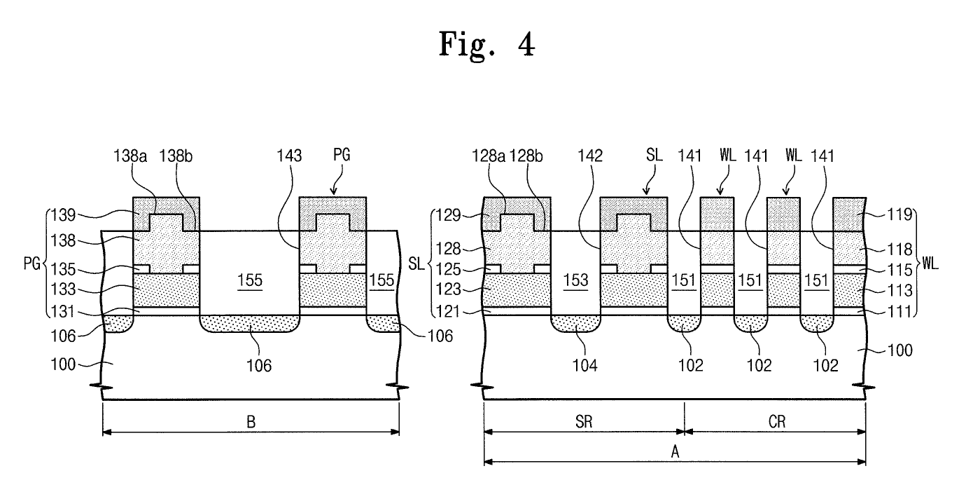

Referring to FIG. 4, the resulting structure of the metal-semiconductor compounding process is disclosed. The reacted upper portions of the control gate layers 117, 127, 137 may change to upper control gate layers 119, 129, 139. The lower portions of the control gate layers 117, 127, 137 may remain unreacted as lower control gate layers 118, 128, 138. As a result, respective word lines WL may be gate structures that include a tunnel dielectric layer 111, a charge storage layer 113, a blocking layer 115, and a lower control gate 118 and an upper control gate layer 119. Respective select lines SL may be gate structures that include a select gate dielectric layer 121, a select underlying gate 123, a select lower control gate layer 128 and a select upper control gate layer 129. Respective peripheral gate structures PG may be gate structures that include a peripheral gate dielectric layer 131, a peripheral underlying gate 133, a peripheral lower control gate layer 138, and a peripheral upper control gate layer 139.

The sidewalls of the gap regions 141, 142, 143 may be re-defined by the sidewalls of the gate structures WL, SL, PG.

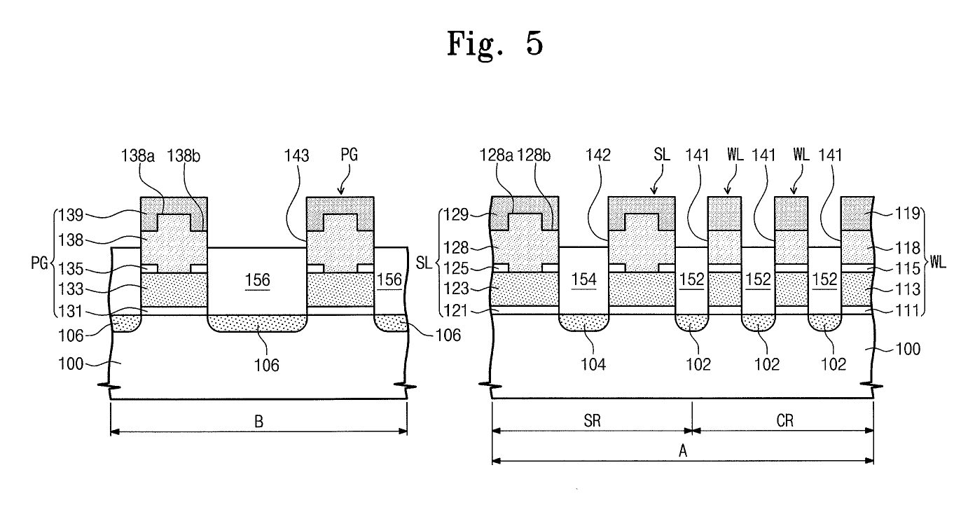

At least portions of the insulation patterned layers 151, 153, 155 may be recessed. The insulation patterned layers 151, 153, 155 may be recessed by isotropic or anisotropic etching process by using dry and/or wet etching method. By recessing the insulation patterned layers 151, 153, 155, recessed insulation patterned layers 152, 154, 156 may be formed, as shown in FIG. 5.

Referring to FIG. 5, the respective recessed insulation patterned layers 152, 154, 156 may have recessed upper surfaces. The recessed upper surfaces may have substantially the same height. Alternatively, the second and the third insulation patterned layers 153, 155 that are wider than the first gap regions 141 may be further recessed than the first insulation patterned layers 151 and, as a result, the upper surface of the recessed second and third insulation patterned layers 154, 156 may be lower than the upper surface of the recessed first insulation patterned layers 152.

The upper surfaces of the recessed insulation patterned layers 152, 154, 156 may be lower than the upper surfaces of the lower control gate layers 118, 128, 138. Specifically, the upper surfaces of the recessed first insulation patterned layers 152 may be lower than the upper surface of the lower control gate layer 118 and may be higher than the upper surface of the blocking layer 115. The upper surface of the recessed second insulation patterned layer 154 may be lower than the second upper surface 128b of the select lower control gate layer 128 and may be higher than the upper surface of the inter-select gate dielectric layer 125. The upper surface of the recessed third insulation patterned layer 156 may be lower than the second upper surface 138b of the peripheral lower control gate layer 138 and may be higher than the upper surface of the inter-peripheral gate dielectric layer 135.

Subsequently, by forming the interlayer dielectric layer 180 as explained referring to FIG. 1, a semiconductor device according to one example embodiment of the present inventive concept can be implemented.

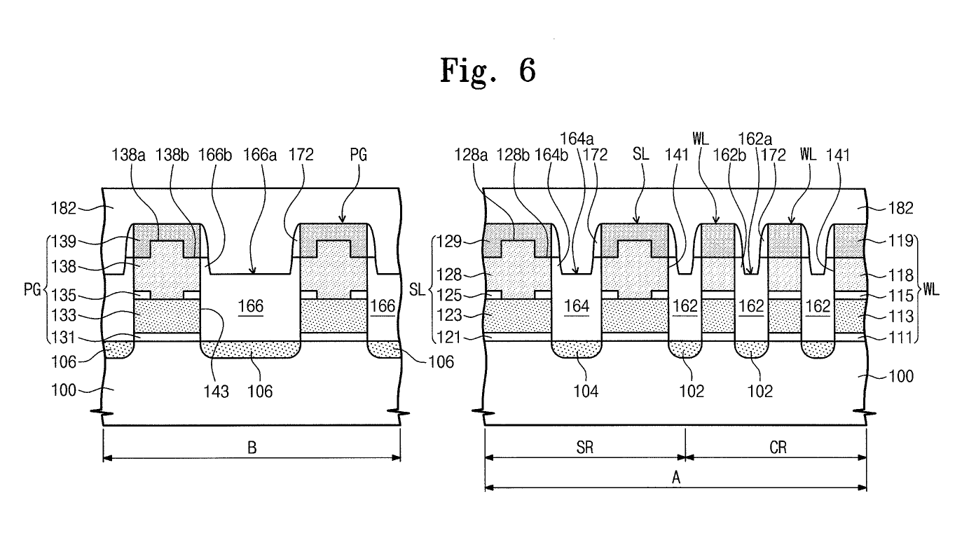

Hereinafter, a semiconductor device according to another exemplary embodiment of the present inventive concept will be explained. FIG. 6 is a cross sectional view illustrating a semiconductor device according to another example embodiment of the present inventive concept. In this embodiment, the same elements as the elements explained referring to FIGS. 1 through 5 will use like reference numerals.

Referring to FIG. 6, a substrate 100 includes a string region A and a peripheral region B. Word lines WL and select lines SL can be disposed on a memory cell region CR and a select region SR of the string region A, respectively, and peripheral gate structures PG can be disposed on the peripheral region B.

Insulation patterned layers 162, 164, 166 may be provided to fill the lower portions of the respective gap regions 141, 142, 143 between the adjoining gate structures WL, SL, PG. The insulation patterned layers 162, 164, 166 may entirely fill the lower portions of the gap regions 141, 142, 143. The lower portion of the first gap regions 141 between the adjoining word lines WL and also between the adjoining word lines WL and select line SL may be filled with a first insulation patterned layer 162. The lower portion of the second gap region 142 between the adjoining select lines SL may be filled with a second insulation patterned layer 164. The lower portion of the third gap region 143 between the adjoining peripheral gate structures PG may be filled with third insulation patterned layers 166.

The respective insulation patterned layers 162, 164, 166 may have upper surfaces 162a, 164a, 166a and protruded portions 162b, 164b, 166b at both sides of the upper surfaces.

Specifically, the first insulation patterned layers 162 may have the first upper surface 162a and the first protruded portions 162b. The first upper surface 162a may be lower than the upper surface of the lower control gate layer 118 and may be higher that the upper surface of the blocking layer 115. The upper surface of the first protruded portions 162b is substantially co-planar with the upper surface of the lower control gate layer 118. The second insulation patterned layer 164 may have the second upper surface 164a and the second protruded portions 164b. The second upper surface 164a may be lower than the second upper surface 128b of the select lower control gate layer 128 and may be higher than the upper surface of the inter-select gate dielectric layer 125. The upper surface of the second protruded portions 164b is substantially co-planar with the second upper surface 128b of the select lower control gate layer 128. The third insulation patterned layer 166 may have the third upper surface 166a and the third protruded portions 166b. The third upper surface 166a may be lower than the second upper surface 138b of the peripheral lower control gate layer 138 and may be higher than the upper surface of the inter-peripheral gate dielectric layer 135. The upper surface of the third protruded portions is substantially co-planar with the second upper surface 138b of the peripheral lower control gate layer 138. The respective areas of the second and third upper surfaces 164a, 166a may be larger than the area of the first upper surface 162a.

Spacers 172 may be disposed on the respective protruded portions 162b, 164b, 166b. The spacers 172 may also be disposed on the sidewalls of the upper control gate layers 119, 129, 139. The spacers 172 may include an oxide, nitride, and/or oxynitride material. The sidewalls of the protruded portions 162b, 164b, 166b and the sidewalls of the spacers 172 on the protruded portions 162b, 164b, 166b may be self-aligned.

An interlayer dielectric layer 182 may be deposited on the gate structures WL, SL, PG, the spacers 172 and the upper surfaces 162a, 164a, 166a. The interlayer dielectric layer 182 may entirely fill the interior spaces surrounded by the spacers 172 and the protruded portions 162b, 164b, 166b

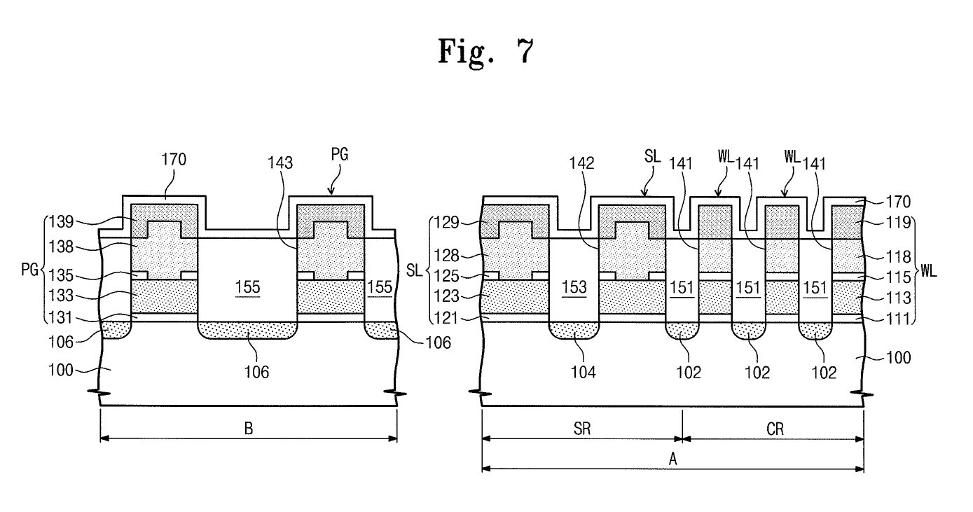

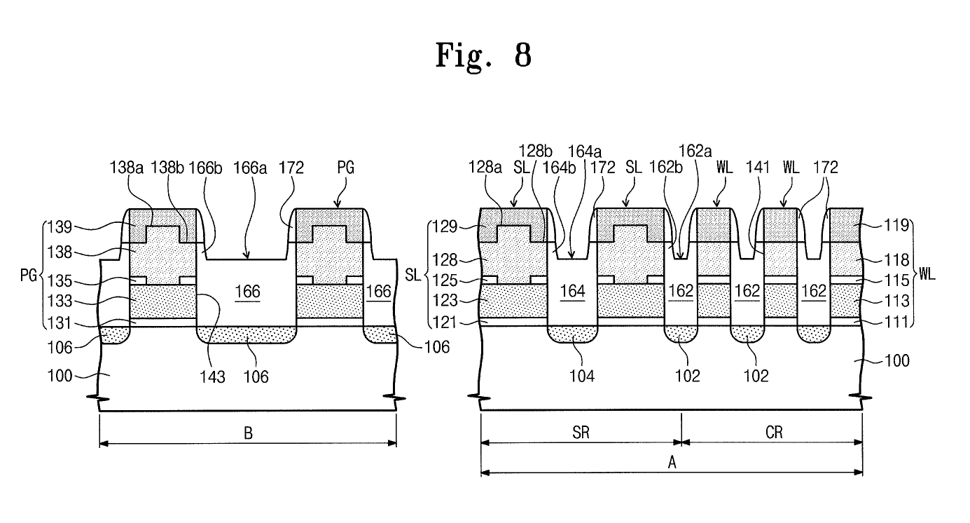

Hereinafter, a semiconductor device manufacturing method according to another exemplary embodiment of the present inventive concept will be explained. FIGS. 7 through 8 are cross sectional views illustrating a method of manufacturing the semiconductor device as shown in FIG. 6.

Referring to FIG. 7, a method of manufacturing a semiconductor device explained referring to FIGS. 2 through 4 is provided. A spacer layer 170 may be formed on gate structures WL, SL, PG and insulation patterned layers 151, 153, 155. The spacer layer 170 may be conformally deposited on the upper surface and sidewall of the upper control gate layer 119, the upper surface and sidewall of the select upper control gate layer 129, the upper surface and sidewall of the peripheral upper control gate layer 139, and the upper surface of the insulation patterned layers 151, 153, 155. The thickness of the spacer layer 170 may be less than half width of the first space between the adjoining word lines WL so that the spacer layer 170 may not completely fill the first space and the resulting empty spaces are surrounded by the spacer layer 170.

The spacer layer 170 and the insulation patterned layers 151, 153, 155 can be etched. The spacer layer 170 and the insulation patterned layers 151, 153, 155 may be anisotropically etched using dry and/or wet etching method to form spacers 172 as shown in FIG. 8.

Referring to FIG. 8, the spacers 172 can be formed on the sidewalls of the upper control gate layers 119, 129, 139. Portions of the insulation patterned layers 151, 153, 155 under the spacers 172 may not be etched and the central portion of the insulation patterned layers 151, 153, 155 may be etched to have recessed upper surfaces 162a, 164a, 166a. As a result, protruded portions 162b, 164b, 166b at both sides of the recessed upper surfaces 162a, 164a, 166a may be formed.

The first recessed upper surface 162a may be lower than the upper surface of the lower control gate layer 118, the second recessed upper surface 164a may be lower than the upper surface 128b of the select lower control gate layer 128, and the third recessed upper surface 166a may be lower than the upper surface 138b of the peripheral lower control gate layer 138

The sidewalls of the protruded portions 162b, 164b, 166b and the sidewalls of the spacers 172 on the protruded portions 162b, 164b, 166b may be self-aligned. Within the respective gap regions 141, 142, 143, empty interior spaces surrounded by the sidewalls of the protruded portions 162b, 164b, 166b and the sidewalls of the spacers 172 on the protruded portions 162b, 164b, 166b may be defined.

The interlayer dielectric layer 182, referring to FIG. 6, may be provided to be deposited on the spacers 172 and the gate structures WL, SL, PG. As a result, a semiconductor device according to still another exemplary embodiment of the present invention may be implemented.

Semiconductor devices according to exemplary embodiments of the present inventive concept can be implemented in various forms of semiconductor packages. For example, semiconductor devices according to exemplary embodiments of the present inventive concept can be packaged by various packaging methods such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat Pack (TQFP), Small Outline (SOIC), Shrink Small Outline Package (SSOP), Thin Small Outline Package (TSOP), Thin Quad Flat Pack (TQFP), System In Package (SIP), Multi Chip Package (MCP), Wafer-level Fabricated Package (WFP), Wafer-Level Processed Stack Package (WSP). The packages mounting semiconductor devices according to exemplary embodiments of the present inventive concept may further comprise controllers and/or logic devices to control the semiconductor devices.

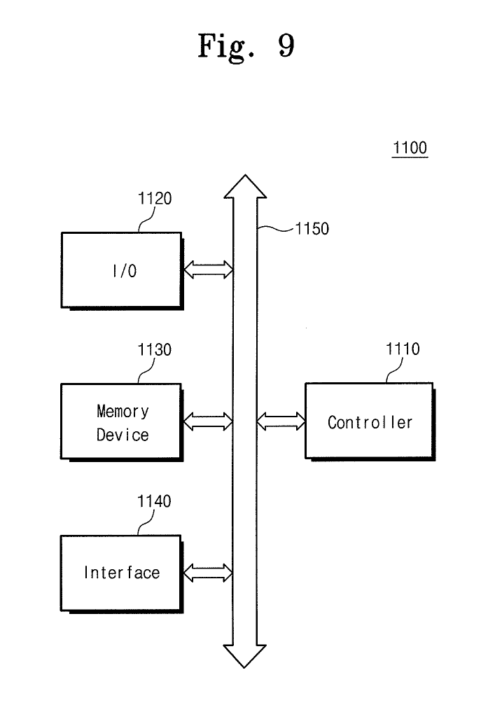

FIG. 9 is a simplified block diagram illustrating an electronic system including a semiconductor device according to exemplary embodiments of the present inventive concept.

Referring to FIG. 9, an electronic system 1100 comprises a controller 1110, an input/output device (I/O) 1120, a memory device 1130, an interface 1140 and a bus 1150. The controller 1110, the input/output device 1120, the memory device 1130 and/or the interface 1140 can be coupled each other through the bus 1150. The bus 1150 corresponds to a data communication path.

The controller 1100 may include at least one selected from the group consisting of a microprocessor, a digital signal processor, a microcontroller and a logic device performing similar functions to the foregoing devices. The input/output device 1120 may include keypad, keyboard and display devices. The memory device 1130 may store data and/or instructions. The memory device 1130 may include at least one semiconductor device disclosed herein according to exemplary embodiments of the present inventive concept. Further, the memory device 1130 may further comprise different forms of semiconductor memory devices such as DRAM and/or SRAM devices. The interface 1140 may send data to communication network or receive data from the communication network. The interface 1140 may be wireless or wired. For example, the interface 1140 may include an antenna or wired/wireless transceiver. Although not illustrated herein, the electronic system 1100 may further comprise a high speed DRAM and/or SRAM as an operation memory to improve operation of the controller 1110.

The electronic system 1100 may be applied to Personal Digital Assistant (PDA), portable computer, web tablet, wireless phone, mobile phone, digital music player), memory card, or various kinds of electronic equipment that can wirelessly send and receive data.

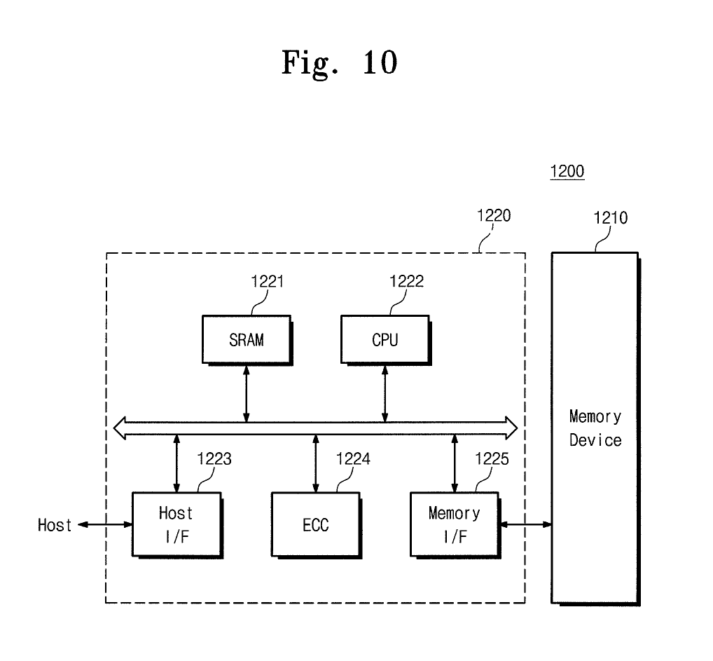

FIG. 10 is a block diagram illustrating a memory card including a semiconductor device according to exemplary embodiments of the present inventive concept.

Referring to FIG. 10, a memory card 1200 according to exemplary embodiments of the present inventive concept may include a memory device 1210. The memory device 1210 may include at least one semiconductor device disclosed herein according to exemplary embodiments of the present inventive concept. Further, the memory device 1210 may further comprise different forms of semiconductor memory devices such as DRAM and/or SRAM devices. The memory card 1200 may further comprise a memory controller 1220 controlling data exchange between a host and the memory device 1210.

The memory controller 1220 may include a processing unit to control overall operation of the memory card. The memory controller 1220 may further comprise an SRAM 1221 used as an operation memory of the processing unit. Further, the memory controller 1220 may further comprise a host interface 1223 and a memory interface 1225. The host interface 1223 may be equipped with a data exchange protocol between the memory card 1200 and the host. The memory interface 1225 may couple the memory controller 1220 with the memory device 1210. The memory controller 1220 may still further comprise an error correction block (Ecc) 1224. The error correction block 1224 may detect and correct errors in the read-out data from the memory device 1210. Although not illustrated herein, the memory card 1200 may further comprise a ROM device storing code data for interfacing with the host. The memory card 1200 may be used as a portable data storage card. Specifically, the memory card 1200 can be implemented as solid-state disks, which can replace conventional hard disks of computer systems.

Although a few exemplary embodiments of the present inventive concept have been described with reference to the enclosed drawings, those who are skilled in the art will readily appreciate that various modifications are possible from the exemplary embodiments without materially departing from the novel teachings and advantages of the present inventive concept. Accordingly, the exemplary embodiments disclosed hereinabove are to explain the present inventive concept and should not be used to limit the meaning or the scope of the invention defined in the claims.

1. A semiconductor device comprising:
a plurality of gate structures disposed on a substrate, respective gate structures including a lower control gate layer and an upper control gate layer, the upper control gate layer being disposed on the lower control gate layer and including a different material from the lower control gate layer; and
insulation patterned layers disposed in gap regions defined between the respective gate structures adjacent to each other, upper surfaces of the insulation patterned layers being lower than an upper surface of the lower control gate layer.

2. The semiconductor device of claim 1, wherein at least one of the plurality of gate structures includes a tunnel dielectric layer, a charge storage layer, and a blocking layer sequentially stacked between the substrate and the lower control gate, and the upper surfaces of the insulation patterned layers are higher than an upper surface of the blocking layer.

3. The semiconductor device of claim 1, wherein the upper surfaces of the insulation patterned layers are substantially even.

4. The semiconductor device of claim 1, wherein at least one of the plurality of gate structures includes an underlying gate layer, a gate dielectric layer, and an inter-gate dielectric layer sequentially stacked between the substrate and the lower control gate layer, and the lower control gate layer penetrates through the inter-gate dielectric layer to contact with the underlying gate layer.

5. The semiconductor device of claim 5, wherein the lower control gate layer includes a first upper surface and second upper surfaces disposed on both sides of the first upper surface, the second upper surfaces being lower than the first upper surface and higher than the upper surfaces of the insulation patterned layers.

6. The semiconductor device of claim 1, further comprising an interlayer dielectric layer disposed on the insulation patterned layers and the plurality of gate structures.

7. The semiconductor device of claim 1, wherein the insulation patterned layers have protruded portions at both sides of the upper surfaces of the insulation patterned layers.

8. The semiconductor device of claim 7, further comprising spacers disposed on the protruded portions and sidewalls of the upper control gate layer.

9. The semiconductor device of claim 8, wherein the protruded portions have sidewalls self-aligned to the sidewalls of the spacers.

10. The semiconductor device of claim 1, wherein a resistivity of the upper control gate layer is lower than a resistivity of the lower control gate layer.

11. The semiconductor device of claim 1, wherein the different material comprises a metal.

12-17. (canceled)

18. A semiconductor device comprising:
a first gate structure including a lower control gate layer and an upper control gate layer, the upper control gate layer including a metal silicide;
a second gate structure including a lower control gate and an upper control gate layer and being distant from the first gate structure at a first space width; and
a first isolation patterned layer filling a gap between the first and the second gate structure and having an upper surface lower than an upper surface of the lower control gate layer of the first gate structure.

19. The semiconductor device of claim 18, further comprising:
a third gate structure including a lower control gate layer and an upper control gate layer, the upper control gate layer including a metal silicide;
a fourth gate structure including a lower control gate and an upper control gate layer and being distant from the third gate structure at a second space width wherein the second space width is larger than the first space width; and
a second isolation patterned layer filling a gap between the third and the fourth gate structure and having an upper surface lower than an upper surface of the lower control gate layer of the third gate structure.

20. The semiconductor device of claim 19, wherein the upper surface of the second isolation patterned layer is lower than the upper surface of the first isolation patterned layer.
